(19) United States
(12) Patent Application Publication
(10) Pub. No.: US 2025/0316220 A1
(43) Pub. Date: Oct. 9, 2025

(54) DISPLAY PANEL AND ELECTRONIC DEVICE INCLUDING THE SAME

(71) Applicant: Samsung Display Co., Ltd., Yongin-si (KR)

(72) Inventors: Inho Park, Yongin-si (KR); Jinyool Kim, Yongin-si (KR)

(73) Assignee: Samsung Display Co., Ltd., Yongin-si (KR)

(21) Appl. No.: 19/092,473

(22) Filed: Mar. 27, 2025

(30) Foreign Application Priority Data
Apr. 9, 2024 (KR) 10-2024-0047906

(51) Int. Cl. G09G 3/32; G09G 3/00

(52) U.S. Cl. CPC G09G 3/32; G09G 3/006; G09G 2300/0426; G09G 2330/08

(57) ABSTRACT

A display panel and an electronic device including the display panel are provided. The display panel includes a pixel circuit disposed in a display area, a light-emitting diode disposed in the display area, a repair circuit disposed in a peripheral area outside of the display area, a repair line extending from the peripheral area to the display area in a first direction, a voltage line extending in the first direction, and a first connection line electrically connecting the repair line to the voltage line.

### CROSS-REFERENCE TO RELATED APPLICATION(S)

This application claims priority to and benefits of Korean Patent Application No. 10-2024-0047906 under 35 U.S.C. § 119, filed on Apr. 9, 2024, in the Korean Intellectual Property Office, the entire contents of which are incorporated herein by reference.

### BACKGROUND

### 1. Technical Field

One or more embodiments relate to a display panel and an electronic device including the same.

### 2. Description of the Related Art

Display panels may include pixels. Each pixel may include a light-emitting element including an emission layer and a pixel circuit for controlling luminance, etc., of the light-emitting element. The pixel circuit may include thin-film transistors, capacitors, and wires.

Display panels have recently become thinner and lighter in weight and thus may be applied to various electronic devices. As display panels have become widely used as described above, various types of display panels and electronic devices including the same have been designed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

A defect in some pixel circuits may cause bright or dark spots to appear on a display panel. To solve various problems including the above problem, one or more embodiments include a display apparatus including a repair pixel circuit electrically connected to a light-emitting element instead of a defective pixel circuit and an electronic device. However, such a technical problem is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display panel may include a pixel circuit disposed in a display area; a light-emitting diode disposed in the display area; a repair circuit disposed in a peripheral area outside of the display area; a repair line extending from the peripheral area to the display area in a first direction; a voltage line extending in the first direction; and a first connection line electrically connecting the repair line to the voltage line.

According to an embodiment, the pixel circuit may include a first transistor including a semiconductor layer and a first gate electrode and electrically connected between a driving voltage line and a second node, wherein the first gate electrode may be disposed over the semiconductor layer and electrically connected to a first node, a second transistor electrically connected between the first node and a data line, a capacitor including a second electrode electrically connected between the first node and the second node, a third transistor electrically connected between the first node and a first voltage line, a fourth transistor electrically connected between the second node and a third node to which a pixel electrode of the light-emitting diode is electrically connected, and a fifth transistor electrically connected between the third node and a second voltage line.

According to an embodiment, the voltage line may include one of the first voltage line and the second voltage line.

According to an embodiment, the pixel circuit may further include a sixth transistor electrically connected between the second node and a third voltage line, wherein the voltage line may include one of the first voltage line, the second voltage line, and the third voltage line.

According to an embodiment, the light-emitting diode may include a pixel electrode, a common electrode disposed over the pixel electrode, and an intermediate layer disposed between the pixel electrode and the common electrode, wherein the voltage line may include a common voltage line that transfers a common voltage to the common electrode.

According to an embodiment, the semiconductor layer may include an oxide semiconductor material, wherein the first connection line and the semiconductor layer may be disposed in a same layer.

According to an embodiment, the display panel may further include a first insulating layer disposed below the semiconductor layer, wherein the repair line may be disposed below the first insulating layer.

According to an embodiment, the first connection line may include a conductive oxide material.

According to an embodiment, the first connection line may include a metal, wherein a thickness of the first connection line may be about 1,000 Å or less.

According to an embodiment, the display panel may further include a second connection line electrically connecting the pixel circuit or the repair line to the light-emitting diode.

According to an embodiment, the display panel may further include a third connection line electrically connected to the repair circuit and overlapping the repair line, wherein, in case that the second connection line is electrically connected to the repair line, the third connection line may be electrically connected to the repair line.

According to an embodiment, in case that the second connection line is electrically connected to the repair line, the first connection line may be cut, and the repair line and the voltage line may be electrically separated from each other.

According to an embodiment, the repair line may overlap the voltage line in a plan view.

According to one or more embodiments, an electronic device may include a display panel including a display area in which a plurality of pixels are disposed and a peripheral area outside of the display area, wherein the display panel may include a pixel circuit disposed in the display area; a light-emitting diode disposed in the display area; a repair circuit disposed in the peripheral area outside of the display area; a repair line extending from the peripheral area to the display area in a first direction; a voltage line extending in the first direction; and a first connection line electrically connecting the repair line to the voltage line.

According to an embodiment, the pixel circuit may include a first transistor including a semiconductor layer and a first gate electrode and electrically connected between a driving voltage line and a second node, wherein the first gate electrode may be disposed over the semiconductor layer and electrically connected to a first node, a second transistor electrically connected between the first node and a data line, a capacitor including a second electrode electrically connected between the first node and the second node, a third transistor electrically connected between the first node and a first voltage line, a fourth transistor electrically connected between the second node and a third node to which a pixel electrode of the light-emitting diode is electrically connected, and a fifth transistor electrically connected between the third node and a second voltage line.

According to an embodiment, the voltage line may include one of the first voltage line and the second voltage line.

According to an embodiment, the pixel circuit may further include a sixth transistor electrically connected between the second node and a third voltage line, wherein the voltage line may include one of the first voltage line, the second voltage line, and the third voltage line.

According to an embodiment, the semiconductor layer may include an oxide semiconductor material.

According to an embodiment, the display panel may further include a second connection line electrically connecting the light-emitting diode to the pixel circuit or the repair line, wherein, in case that the second connection line is electrically connected to the repair line, the first connection line may be cut, and the repair line and the voltage line may be electrically separated from each other.

According to an embodiment, the first connection line may include a conductive oxide material.

According to an embodiment, the first connection line may include a metal, wherein a thickness of the first connection line may be about 1,000 Å or less.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view of a display panel according to an embodiment;

FIG. 2 is a schematic plan view of a display panel according to an embodiment;

FIG. 3A is a schematic diagram showing part of a display panel according to an embodiment;

FIG. 3B is a schematic diagram describing a method of repairing a defective pixel in the display panel shown in FIG. 3A;

FIG. 4A is a schematic diagram of an equivalent circuit showing a repair circuit and one pixel according to an embodiment;

FIG. 4B is a schematic diagram describing a method of repairing a defective pixel in a display panel according to an embodiment;

FIGS. 5A and 5B are each a schematic diagram of an equivalent circuit showing a repair circuit and one pixel according to an embodiment;

FIG. 6A is a schematic cross-sectional view of a display panel according to an embodiment;

FIG. 6B is a schematic cross-sectional view describing a method of repairing a defective pixel in the display panel shown in FIG. 6A;

FIG. 7 is a schematic plan view of part of a display panel according to an embodiment;

FIG. 8A is a schematic cross-sectional view of a display panel according to an embodiment;

FIG. 8B is a schematic cross-sectional view describing a method of repairing a defective pixel in the display panel shown in FIG. 8A;

FIG. 9 is a schematic cross-sectional view of a display panel according to an embodiment; and

FIG. 10 is a schematic perspective view of an electronic device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

As the description allows for various changes and numerous embodiments, embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof may be omitted.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

It will be understood that the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or element is referred to as being on another layer, region, or element, it may be directly or indirectly on the other layer, region, or element. For example, intervening layers, regions, or elements may be present.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When an embodiment may be implemented differently, a certain process order may be performed differently from the described order. For example, two consecutively described processes may be performed substantially at the same time or performed in an order opposite to the described order.

Sizes of elements in the drawings may be exaggerated or reduced for convenience of explanation. For example, since sizes and thicknesses of elements in the drawings may be arbitrarily illustrated for convenience of description, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

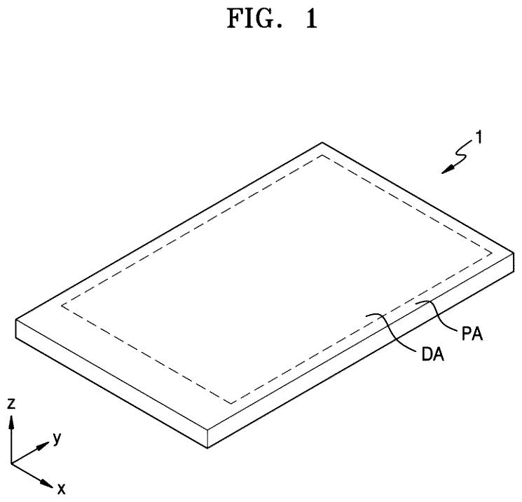

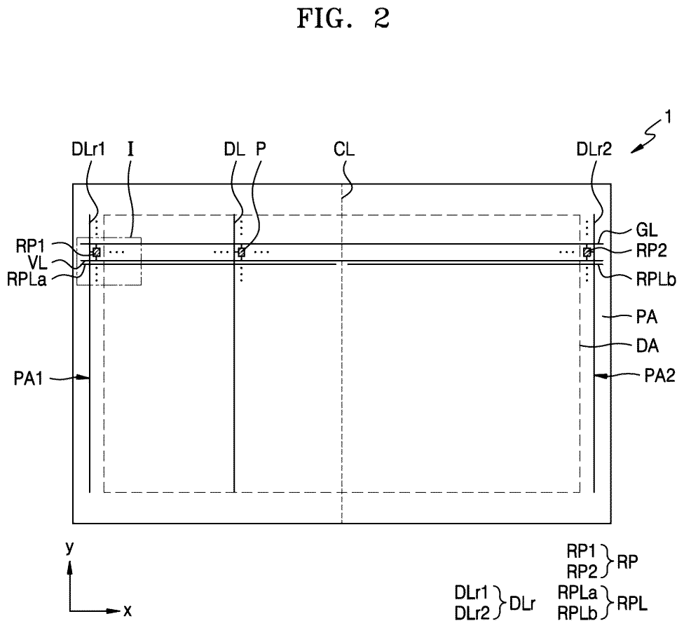

FIG. 1 is a schematic perspective view of a display panel 1 according to an embodiment. FIG. 2 is a schematic plan view of the display panel 1 according to an embodiment.

Referring to FIG. 1, the display panel 1 may include a display area DA displaying an image and a peripheral area PA outside of the display area DA. The display area DA may be entirely surrounded by the peripheral area PA.

In a plan view of the display area DA, the display area DA may have a rectangular shape. In an embodiment, the display area DA may have a polygonal shape, such as a triangle, a pentagon, or a hexagon, a circular shape, an oval shape, or an atypical shape. Corners of edges of the display area DA may have round shapes.

Referring to FIG. 2, the display panel 1 may include pixels P arranged (or disposed) in the display area DA. The pixels P may be arranged in various forms, such as a stripe arrangement, a PENTILE™ arrangement (a diamond arrangement) and a mosaic arrangement, to display an image. Each pixel P may include a light-emitting element (for example, a light-emitting diode), and the light-emitting element may be electrically connected to a pixel circuit. According to an embodiment, each of the pixels P may emit light of a different color. According to an embodiment, each of the pixels P may emit red, green, or blue light. According to an embodiment, each of the pixels P may emit red, green, blue, or white light. The display panel 1 may display an image by using light emitted from the pixels P. Each pixel circuit may be electrically connected to a gate line GL, a voltage line VL, and a data line DL, and may include transistors and at least one capacitor.

Repair pixels RP may be arranged in the peripheral area PA. Each of the repair pixels RP may include a repair circuit but may not include a light-emitting element. Each repair circuit may be electrically connected to the gate line GL, the voltage line VL, and a repair data line DLr, and may have substantially the same or similar configuration as that of the pixel circuit of the pixel P.

The peripheral area PA may include a first peripheral area PA1 and a second peripheral area PA2 facing each other with the display area DA therebetween. According to an embodiment, the repair pixels RP may include first repair pixels RP1 arranged in the first peripheral area PA1 and second repair pixels RP2 arranged in the second peripheral area PA2. Repair data lines DLr may include a first repair data line DLr1 arranged in the first peripheral area PA1 and a second repair data line DLr2 arranged in the second peripheral area PA2. The first repair pixels RP1 may be electrically connected to the first repair data line DLr1, and the second repair pixels RP2 may be electrically connected to the second repair data line DLr2.

Data lines DL may extend in a second direction (for example, a y-axis direction) in the display area DA and may be configured to transmit a data signal to the pixels P connected thereto. The first repair data line DLr1 may extend in the second direction (for example, the y-axis direction) in the first peripheral area PA1 and may be configured to transmit a first repair data signal to the first repair pixels RP1. The second repair data line DLr2 may extend in the second direction (for example, the y-axis direction) in the second peripheral area PA2 and may be configured to transmit a second repair data signal to the second repair pixels RP2.

Gate lines GL and voltage lines VL may extend in a first direction (for example, an x-axis direction) and be connected to the pixels P and the repair pixels RP that are in the same row. Each of the gate lines GL may be configured to transmit a gate signal to the pixels P and the repair pixels RP connected thereto.

Each of the voltage lines VL may be configured to transfer a constant voltage to the pixels P and the repair pixels RP connected thereto. According to an embodiment, a constant voltage transferred by the voltage line VL may be an initialization voltage for initializing a node of each pixel circuit and repair circuit. According to an embodiment, a constant voltage transferred by the voltage line VL may be a common voltage applied to an opposite electrode of the light-emitting element.

The display panel 1 may further include repair lines RPL extending from the peripheral area PA to the display area DA in the first direction (for example, the x-axis direction). A repair line RPL may be connectable to any one repair pixel RP and light-emitting elements of the pixels P arranged in the same row. In this regard, the description that the repair line RPL is ‘connectable’ to the repair pixel RP and the light-emitting element of the pixel P indicates a state in which the repair line RPL has not been connected to the repair pixel RP and the pixel P but may be connected thereto through a repair process. In case that the repair line RPL is not connected to the repair pixel RP and the light-emitting element of the pixel P, the repair line RPL may be electrically connected to the voltage line VL. Although FIG. 2 shows the repair line RPL and the voltage line VL adjacent to each other, one or more embodiments are not limited thereto. According to an embodiment, the repair line RPL may overlap the voltage line VL in a plan view.

Various conductive lines configured to transmit an electric signal to be applied to the display area DA, outer circuits electrically connected to pixel circuits, and pads on which a printed circuit board or driver integrated circuit (IC) chips are attached may be positioned in the peripheral area PA. For example, a gate driving circuit, a data driving circuit, a power supply circuit, and a controller may be provided in the peripheral area PA.

During the manufacturing process, some pixel circuits may be damaged, resulting in a defective pixel such as a bright spot that is brighter than adjacent pixels P or a dark spot that is darker than adjacent pixels P on the display panel 1. In this regard, a light-emitting element of the defective pixel may be electrically connected to the repair pixel RP through the repair line RPL to operate normally.

According to an embodiment, the repair lines RPL may include left (for example, negative x-axis direction) repair lines RPLa extending from the first peripheral area PA1 toward a virtual center line CL bisecting the display area DA and right (for example, positive x-axis direction) repair lines RPLb extending from the second peripheral area PA2 toward the virtual center line CL. A left repair line RPLa and a right repair line RPLb in the same row may be apart from each other in the first direction (for example, the x-axis direction). A light-emitting element of a defective pixel positioned left (for example, in a negative x-axis direction) to the virtual center line CL may be electrically connected to a first repair pixel RP1 through the corresponding left repair line RPLa. A light-emitting element of a defective pixel positioned right (for example, in a positive x-axis direction) to the virtual center line CL may be electrically connected to a second repair pixel RP2 through the corresponding right repair line RPLb.

According to an embodiment, the first repair pixel RP1 and the first repair data line DLr1 may be omitted, or the second repair pixel RP2 and the second repair data line DLr2 may be omitted. For example, the repair line RPL may not be divided into left and right with respect to the virtual center line CL but may be provided as a single line intersecting the display area DA.

Although FIG. 2 shows that the pixels P and the repair pixels RP arranged in the same row are connected to one gate line GL, this is an example, and the pixels P and the repair pixels RP arranged in the same row may be connected to two or more gate lines, and the gate driving circuit may be configured to supply two or more gate signals of which timings at which an on voltage is applied are different from each other to the corresponding gate lines.

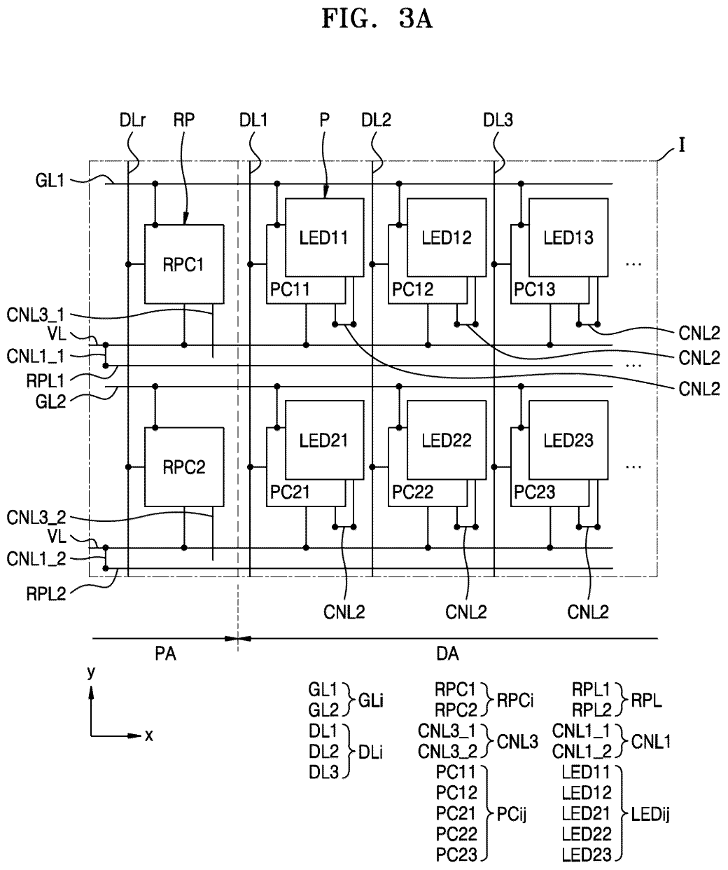

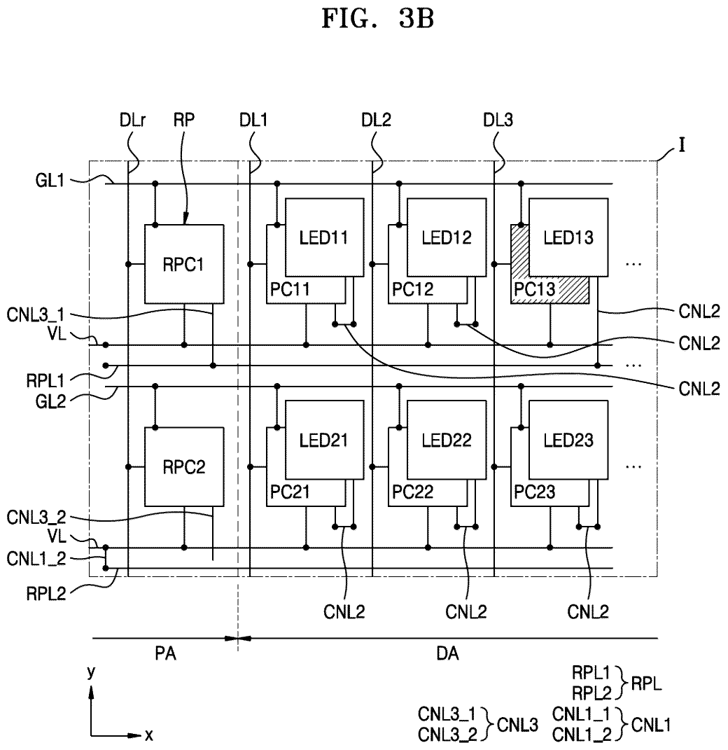

FIG. 3A is a schematic diagram showing part of a display panel according to an embodiment. FIG. 3B is a schematic diagram describing a method of repairing a defective pixel in the display panel shown in FIG. 3A. FIG. 3A and FIG. 3B are schematic diagram of the region I in FIG. 2.

Referring to FIG. 3A, the display panel 1 (see FIG. 1) may include pixels arranged in the display area DA and repair pixels arranged in the peripheral area PA. For ease of understanding, FIGS. 3A and 3B show only six pixels and two repair pixels, but one or more embodiments are not limited thereto. m×n pixels may be arranged, for example, in a matrix, in the display area DA, and m repair pixels may be arranged in a column direction (for example, a second direction or a y-axis direction) in the peripheral area PA. According to an embodiment, m repair pixels may be arranged in the column direction at each of the two sides of the display area DA.

A pixel in an i-th row and j-th column may include a light-emitting diode LEDij as a light-emitting element and a pixel circuit PCij connected to the light-emitting diode LEDij. A repair pixel in an i-th row may include a repair circuit RPCi. In this regard, i is a natural number of 1 to m, and j is a natural number of 1 to n.

Data lines DL1, DL2, DL3, . . . , DLn may each extend in a second direction (for example, a y-axis direction) and be configured to transmit data signals to pixel circuits PC that are in the same column. The repair data line DLr may extend in the second direction (for example, the y-axis direction) and be configured to transmit repair data signals to repair circuits RPC. Gate lines GL1, GL2, . . . , GLm may each extend in a first direction (for example, an x-axis direction) and be configured to transmit a scan signal to pixel circuits PC and repair circuits RPC that are in the same row. The pixel circuit PCij in the i-th row and j-th column is connected to a gate line GLi and a data line DLj. The repair circuit RPCi in the i-th row is connected to the gate line GLi and the repair data line DLr. M voltage lines VL may each extend in the first direction (for example, the x-axis direction) and be configured to transfer a constant voltage to pixel circuits PC and a repair circuit RPC that are in the same row.

M repair lines RPL may each extend in the first direction (for example, the x-axis direction) and may be electrically connected to the voltage line VL through first connection lines CNL1. A first connection line CNL1 may include a 1st-1 connection line CNL1_1 connecting a first repair line RPL1 to the voltage line VL and a 1st-2 connection line CNL1_2 connecting a second repair line RPL2 to the voltage line VL.

The repair lines RPL may be adjacent to or partially overlap elements and signal lines of the pixel circuit PC. As a comparative example, in case that repair lines are not electrically connected to a voltage line but are in a floating state, parasitic capacitance generated between adjacent elements and the repair lines may cause deterioration of image quality, such as mura, on a display panel. According to one or more embodiments, the repair lines RPL that are not connected to a defective pixel may be electrically connected to the voltage line VL through the first connection line CNL1, and thus, parasitic capacitance between the repair lines RPL and adjacent elements may be reduced.

The pixel circuit PCij may be electrically connected to the light-emitting diode LEDij through a second connection line CNL2. The pixel circuit PCij may include a driving transistor configured to control, based on a data signal, the magnitude of a current flowing to the light-emitting diode LEDij. The light-emitting diode LEDij may emit light at a luminance corresponding to the magnitude of a current received from the driving transistor, and thus, each pixel may express a gray level corresponding to the data signal.

A third connection line CNL3 may be able to connect the repair circuit RPCi and a corresponding repair line RPLi to each other. For example, the third connection line CNL3 may include a 3rd-1 connection line CNL3_1 connecting a first repair circuit RPC1 and the first repair line RPL1 to each other and a 3rd-2 connection line CNL3_2 connecting a second repair circuit RPC2 and the second repair line RPL2 to each other. The 3rd-1 connection line CNL3_1 may overlap the first repair line RPL1 in a plan view, and at least one insulating layer may be disposed between the 3rd-1 connection line CNL3_1 and the first repair line RPL1. Accordingly, the 3rd-1 connection line CNL3_1 and the first repair line RPL1 may be electrically separated from each other. In the same manner, the 3rd-2 connection line CNL3_2 and the second repair line RPL2 may be electrically separated from each other.

Referring to FIG. 3B, a defect may occur in a pixel circuit of any one of pixels. In FIG. 3B, a method of repairing a defective pixel is described based on the assumption that a pixel circuit PC13 (hereinafter, a defective pixel circuit) in a first row and third column has a defect.

A light-emitting diode LED13 of a defective pixel may be electrically separated from the defective pixel circuit PC13 and may be electrically connected to the first repair line RPL1. For example, a portion of the second connection line CNL2 electrically connecting the light-emitting diode LED13 of the defective pixel and the defective pixel circuit PC13 to each other may be cut, and the second connection line CNL2 and the first repair line RPL1 may be connected to each other. Cutting of the second connection line CNL2 and connection between the second connection line CNL2 and the first repair line RPL1 may be performed by laser irradiation.

The repair circuit RPC of a repair pixel positioned in the same row as the defective pixel may be connected to the repair line RPL. For example, the first repair circuit RPC1 may be electrically connected to the first repair line RPL1 through the 3rd-1 connection line CNL3_1. In this regard, a portion of the 1st-1 connection line CNL1_1 may be cut, and the first repair line RPL1 may be electrically separated from the voltage line VL. Connection between the 3rd-1 connection line CNL3_1 and the first repair line RPL1, and cutting of the 1st-1 connection line CNL1_1 may be performed by laser irradiation. Cutting of the second connection line CNL2, connection between the second connection line CNL2 and the first repair line RPL1, connection between the 3rd-1 connection line CNL3_1 and the first repair line RPL1, and cutting of the 1st-1 connection line CNL1_1 may be performed by laser irradiation. Even after a repair process, the second repair line RPL2 in which there is no defective pixel in the corresponding pixel row may be electrically connected to the voltage line VL through the 1st-2 connection line CNL1_2.

Like the pixel circuits PC, the first repair circuit RPC1 may include a driving transistor configured to control the magnitude of a current based on a data signal. The repair data line DLr may be configured to transmit a data signal corresponding to the defective pixel circuit PC13 to the first repair circuit RPC1, and the light-emitting diode LED13 may emit light at a luminance corresponding to the magnitude of a current received from the first repair circuit RPC1 through the first repair line RPL1.

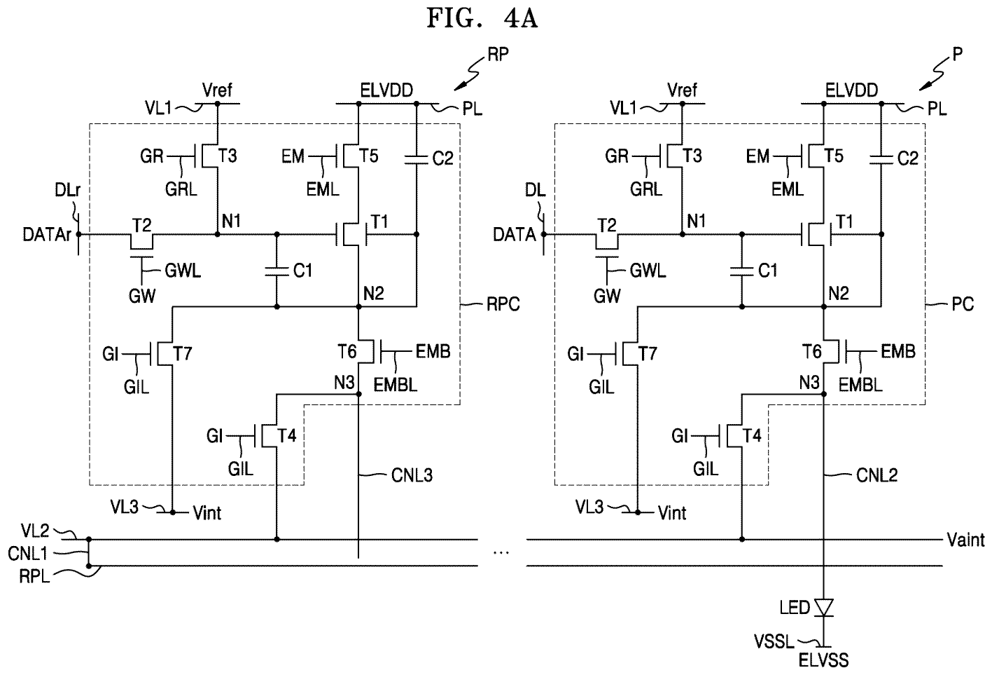

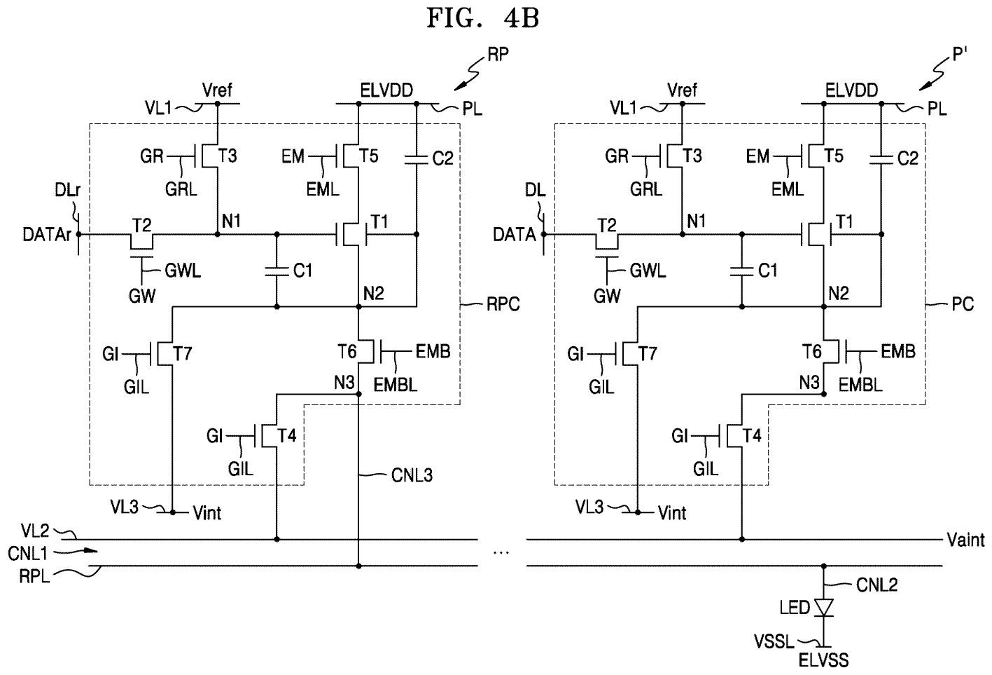

FIG. 4A is a schematic diagram of an equivalent circuit schematically showing the repair pixel RP and one pixel P according to an embodiment.

Referring to FIG. 4A, the repair pixel RP may include the repair circuit RPC, and the pixel P may include the pixel circuit PC and a light-emitting diode LED. The repair pixel RP and the pixel P in the same row may be connected to the same gate lines GWL, GRL, GIL, EML, and EMBL and voltage lines VL1, VL2, and VL3. The repair circuit RPC may have substantially the same or similar configuration as that of the pixel circuit PC. The same or similar configuration is described below focusing on the pixel circuit PC.

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GIL configured to transmit a fourth gate signal GI, a fifth gate line EMBL configured to transmit a fifth gate signal EMB, and the data line DL configured to transmit a data signal DATA. Because light emission of the light-emitting diode LED is controlled by the third gate signal EM and the fifth gate signal EMB, the third gate signal EM and the fifth gate signal EMB may be emission control signals, and the third gate line EML and the fifth gate line EMBL may be referred to as emission control lines. The pixel circuit PC may be electrically connected to a driving voltage line PL configured to transfer a driving voltage ELVDD, a first voltage line VL1 configured to transfer a reference voltage Vref, a second voltage line VL2 configured to transfer a first initialization voltage Vaint, and a third voltage line VL3 configured to transfer a second initialization voltage Vint.

According to an embodiment, transistors included in the pixel circuit PC may be N-type oxide transistors. An oxide transistor may be a transistor of which a semiconductor layer may include an oxide.

The pixel circuit PC may include first to seventh transistors T1 to T7, a first capacitor C1, and a second capacitor C2. The first transistor T1 may be a driving transistor configured to output a driving current corresponding to the data signal DATA, and the second to seventh transistors T2 to T7 may be switching transistors configured to transmit a signal. A first terminal (or a first electrode) and a second terminal (or a second electrode) of each of the first to seventh transistors T1 to T7 may be source (or a source electrode) or drain (or a drain electrode) depending on voltages of the first terminal and the second terminal. For example, depending on voltages of the first terminal and the second terminal, the first terminal may be drain and the second terminal may be source, or the first terminal may be source and the second terminal may be drain. Hereinafter, a node to which a first gate electrode of the first transistor T1 is connected may be defined as a first node N1, and a node to which a second terminal of the first transistor T1 is connected may be defined as a second node N2.

The first transistor T1 may be connected to the driving voltage line PL and the light-emitting diode LED. The first transistor T1 may be connected between the fifth transistor T5 and the sixth transistor T6. The first transistor T1 may include a gate (hereinafter, a first gate electrode) connected to the first node N1, a first terminal, and a second terminal connected to the second node N2. The first transistor T1 may further include a bottom gate connected to the second node N2.

The first terminal of the first transistor T1 may be connected to the driving voltage line PL via the fifth transistor T5, and the second terminal of the first transistor T1 may be connected to a pixel electrode of the light-emitting diode LED via the sixth transistor T6. The first transistor T1 may be configured to receive the data signal DATA according to a switching operation of the second transistor T2 and control the amount of driving current flowing to the light-emitting diode LED.

The second transistor T2 may be connected between the data line DL and the first node N1. The second transistor T2 may include a gate connected to the first gate line GWL, a first terminal connected to the data line DL, and a second terminal connected to the first node N1. The second transistor T2 may be turned on by the first gate signal GW transmitted through the first gate line GWL to transmit the data signal DATA transmitted through the data line DL to the first node N1.

The third transistor T3 may be connected between the first node N1 and the first voltage line VL1. The third transistor T3 may include a gate connected to the second gate line GRL, a first terminal connected to the first node N1, and a second terminal connected to the first voltage line VL1. The third transistor T3 may be turned on by the second gate signal GR transmitted through the second gate line GRL to transfer the reference voltage Vref transferred through the first voltage line VL1 to the first node N1.

The fourth transistor T4 may be connected between a third node N3 and the second voltage line VL2. The fourth transistor T4 may include a gate connected to the fourth gate line GIL, a first terminal connected to the third node N3, and a second terminal connected to the second voltage line VL2. The first terminal of the fourth transistor T4 may be connected to the pixel electrode of the light-emitting diode LED through the third node N3. The fourth transistor T4 may be turned on by the fourth gate signal GI transmitted through the fourth gate line GIL to transfer the first initialization voltage Vaint transferred through the second voltage line VL2 to the third node N3 and initialize the pixel electrode (for example, an anode) of the light-emitting diode LED.

The fifth transistor T5 may be connected to the driving voltage line PL and the first transistor T1. The fifth transistor T5 may include a gate connected to the third gate line EML, a first terminal connected to the driving voltage line PL, and a second terminal connected to the first terminal of the first transistor T1. The fifth transistor T5 may be turned on or turned off according to the third gate signal EM transmitted through the third gate line EML.

The sixth transistor T6 may be connected between the second node N2 and the third node N3. The sixth transistor T6 may include a gate connected to the fifth gate line EMBL, a first terminal connected to the second node N2, and a second terminal connected to the third node N3. The sixth transistor T6 may be turned on or turned off according to the fifth gate signal EMB transmitted through the fifth gate line EMBL.

The seventh transistor T7 may be connected between the second node N2 and the third voltage line VL3. The seventh transistor T7 may include a gate connected to the fourth gate line GIL, a first terminal connected to the second node N2, and a second terminal connected to the third voltage line VL3. The seventh transistor T7 may be turned on by the fourth gate signal GI transmitted through the fourth gate line GIL to transfer the second initialization voltage Vint transferred through the third voltage line VL3 to the second node N2.

According to an embodiment, the second initialization voltage Vint and the first initialization voltage Vaint may be the same voltage. For example, the second terminal of the seventh transistor T7 may be connected to the second voltage line VL2, and the third voltage line VL3 may be omitted.

The first capacitor C1 may be connected between the first node N1 and the second node N2. For example, a first electrode of the first capacitor C1 may be connected to the first node N1, and a second electrode of the first capacitor C1 may be connected to the second node N2. The first capacitor C1 is a storage capacitor and may store voltages corresponding to a threshold voltage of the first transistor T1 and the data signal DATA.

In case that the third transistor T3 and the fifth transistor T5 are turned on, the first transistor T1 may be turned on. In case that a voltage of the second node N2 drops to the difference (Vref−Vth1) between the reference voltage Vref and a threshold voltage (Vth1) of the first transistor T1, the first transistor T1 may be turned off, and a voltage corresponding to the threshold voltage of the first transistor T1 may be stored in the first capacitor C1 to compensate for the threshold voltage of the first transistor T1.

The second capacitor C2 may be connected between the driving voltage line PL and the second node N2. A first electrode of the second capacitor C2 may be connected to the driving voltage line PL, and a second electrode of the second capacitor C2 may be connected to the second node N2.

Capacitance of each of the first capacitor C1 and the second capacitor C2 may vary depending on a color of light emitted from the light-emitting diode LED.

The light-emitting diode LED may be connected to the third node N3 through the second connection line CNL2. The light-emitting diode LED may include a pixel electrode (an anode) connected to the second connection line CNL2 and an opposite electrode (a cathode) facing the pixel electrode. The opposite electrode may receive a common voltage ELVSS through a common voltage line VSSL. A driving current output by the first transistor T1 may flow to the light-emitting diode LED due to the turned-on fifth transistor T5 and the turned-on sixth transistor T6, and the light-emitting diode LED may emit light at a luminance corresponding to the magnitude of the driving current.

The repair pixel RP and the pixel P in the same row may be connected to the same second voltage line VL2. The repair line RPL may be connectable to the repair circuit RPC and the light-emitting diode LED of each of the pixels P. For example, the repair line RPL may overlap each of the second connection line CNL2 and the third connection line CNL3 in a plan view. At least one insulating layer may be disposed between the repair line RPL and the second connection line CNL2 and between the repair line RPL and the third connection line CNL3. Accordingly, the repair line RPL may be electrically separated from the repair circuit RPC and the light-emitting diode LED in an initial state before a repair process. In this regard, the repair line RPL may be electrically connected to the second voltage line VL2 through the first connection line CNL1 to receive the first initialization voltage Vaint.

According to an embodiment, depending on a color of light emitted from the light-emitting diode LED of the pixel P, the first initialization voltage Vaint transferred to the pixel circuit PC may vary. For example, the second voltage line VL2 may include second voltage lines VL2 depending on the color of light emitted by the pixels P, and the repair line RPL may be electrically connected to any one of the second voltage lines VL2 through the first connection line CNL1.

Although FIG. 4A shows the pixel circuit PC and the repair circuit RPC each including seven transistors, one or more embodiments are not limited thereto. According to an embodiment, the pixel circuit PC and the repair circuit RPC may include six transistors. For example, the seventh transistor T7 may be omitted. According to an embodiment, the number of transistors of the pixel circuit PC and the repair circuit RPC may be 5 or less, or 8 or greater.

FIG. 4B is a schematic diagram describing a method of repairing a defective pixel in a display panel according to an embodiment.

Referring to FIG. 4B, a defect may occur in a pixel circuit of any one of the pixels positioned in the same row as the repair pixel RP. A pixel in which a defect has occurred in a pixel circuit is hereinafter referred to as a defective pixel P′.

By cutting a portion of the second connection line CNL2 connecting the pixel circuit PC and the light-emitting diode LED of the defective pixel P′ to each other, the pixel circuit PC and the light-emitting diode LED may be electrically separated from each other. In this regard, another portion of the second connection line CNL2 may be connected to the repair line RPL.

The repair circuit RPC may be electrically connected to a first gate line GWL configured to transmit a first gate signal GW, a second gate line GRL configured to transmit a second gate signal GR, a third gate line EML configured to transmit a third gate signal EM, a fourth gate line GIL configured to transmit a fourth gate signal GI, a fifth gate line EMBL configured to transmit a fifth gate signal EMB, and the repair data line DLr configured to transmit a repair data signal DATAr.

In case that the second connection line CNL2 is connected to the repair line RPL, a third node N3 of the repair circuit RPC may be connected to the repair line RPL through the third connection line CNL3. The first connection line CNL1 connecting the repair line RPL and the second voltage line VL2 to each other may be cut, and thus, the driving voltage line PL and the second voltage line VL2 may be electrically separated from each other. A first transistor T1 of the repair circuit RPC may be configured to receive the repair data signal DATAr according to a switching operation of a second transistor T2 and control the amount of driving current flowing to the repair line RPL.

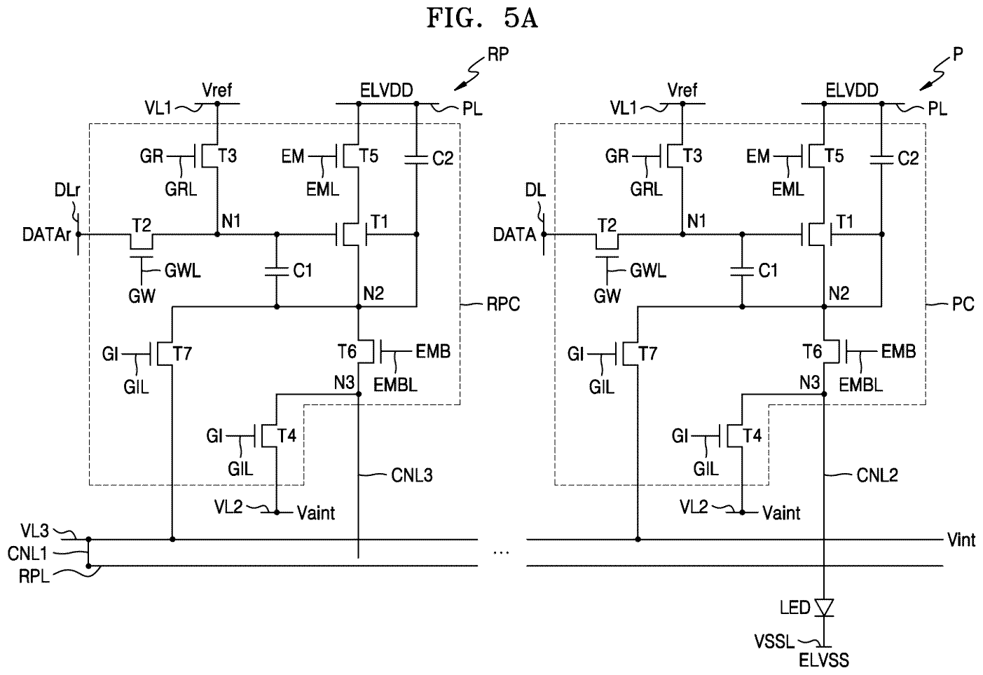

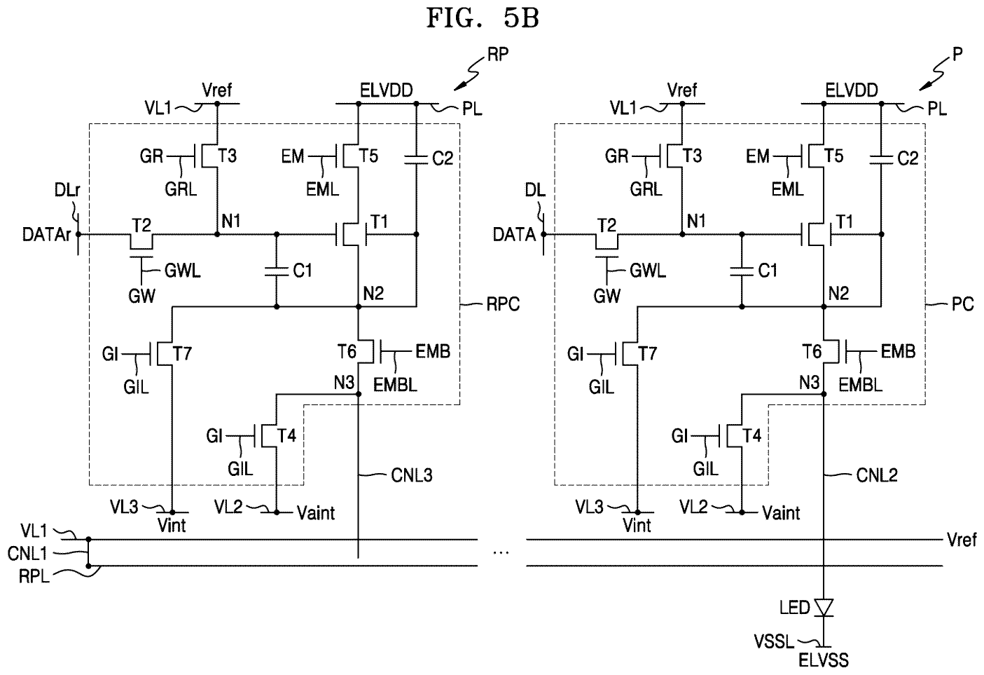

FIGS. 5A and 5B are each a schematic diagram of an equivalent circuit showing the repair circuit RPC and one pixel P according to an embodiment. FIGS. 5A and 5B are similar to FIG. 4A, but a voltage line electrically connected to the repair line RPL through the first connection line CNL1 may be different. A redundant description of the same elements may be omitted below, and differences are described.

Referring to FIGS. 5A and 5B, the repair pixel RP and the pixel P in the same row may be connected to the same gate lines GWL, GRL, GIL, EML, and EMBL and voltage lines VL1, VL2, and VL3. For example, the repair line RPL may overlap each of the second connection line CNL2 and the third connection line CNL3 in a plan view. At least one insulating layer may be disposed between the repair line RPL and the second connection line CNL2 and between the repair line RPL and the third connection line CNL3. Accordingly, the repair line RPL may be electrically separated from the repair circuit RPC and the light-emitting diode LED in an initial state before a repair process.

The repair line RPL may be electrically connected to any one of the voltage lines configured to transfer a constant voltage to the pixel circuit PC and the repair circuit RPC, through the first connection line CNL1. In this regard, the constant voltage may be lower than the driving voltage ELVDD and may be equal to or higher than the common voltage ELVSS. The constant voltage may be the reference voltage Vref, the first initialization voltage Vaint, the second initialization voltage Vint, or the common voltage ELVSS.

According to an embodiment, as shown in FIG. 5A, the repair line RPL may be electrically connected to the third voltage line VL3 through the first connection line CNL1 to receive the second initialization voltage Vint. The third voltage line VL3 may be connected to the seventh transistor T7 of each of the pixel circuit PC and the repair circuit RPC. In case that the seventh transistor T7 is turned on by the fourth gate signal GI transmitted through the fourth gate line GIL, the second initialization voltage Vint may be transferred to the second node N2 to initialize the second node N2.

Depending on a color of light emitted from the light-emitting diode LED of the pixel P, the second initialization voltage Vint transferred to the pixel circuit PC may vary. For example, the third voltage line VL3 may include third voltage lines VL3 depending on the color of light emitted by the pixels P, and the repair line RPL may be electrically connected to any one of the third voltage lines VL3 through the first connection line CNL1.

According to an embodiment, as shown in FIG. 5B, the repair line RPL may be electrically connected to the first voltage line VL1 through the first connection line CNL1 to receive the reference voltage Vref. The first voltage line VL1 may be connected to the third transistor T3 of each of the pixel circuit PC and the repair circuit RPC. In case that the third transistor T3 is turned on by the second gate signal GR transmitted through the second gate line GRL, the reference voltage Vref may be transferred to the first node N1 to initialize the first node N1.

According to an embodiment, the repair line RPL may be electrically connected to the common voltage line VSSL through the first connection line CNL1. The common voltage line VSSL may be a wire arranged in the display area DA, extending in a first direction (for example, an x-axis direction), and configured to transfer the common voltage ELVSS to an opposite electrode of the light-emitting diode LED.

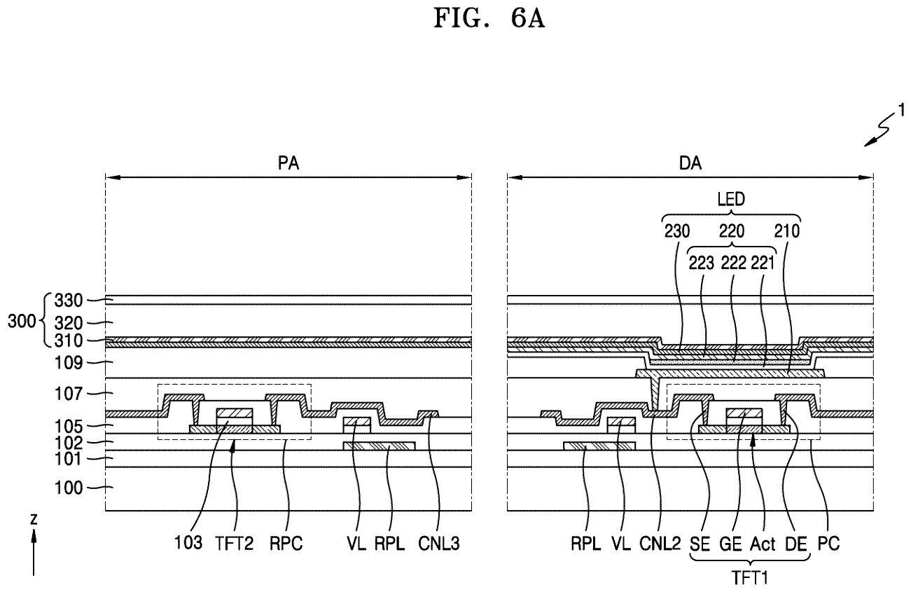

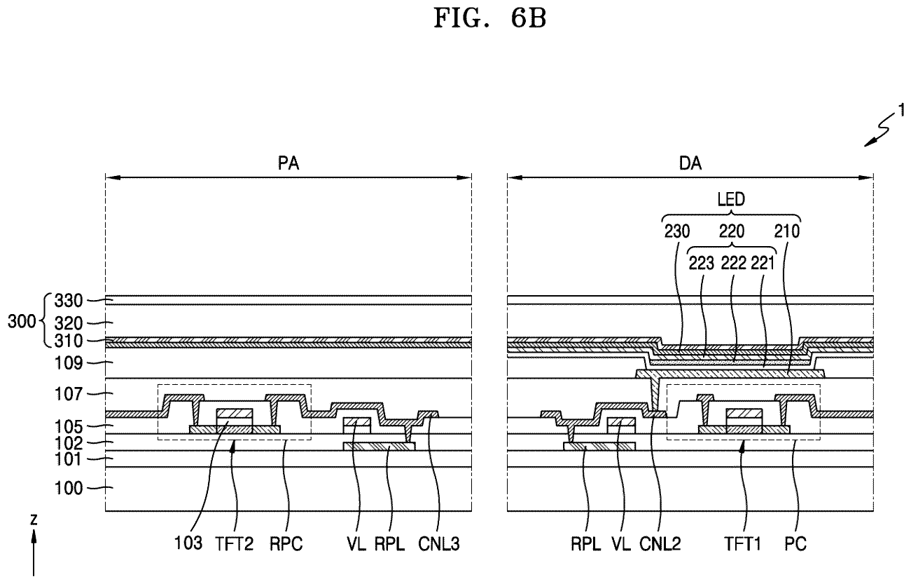

FIG. 6A is a schematic cross-sectional view of the display panel 1 according to an embodiment. FIG. 6B is a schematic cross-sectional view describing a method of repairing a defective pixel in the display panel 1 shown in FIG. 6A.

Referring to FIGS. 6A and 6B, the display panel 1 may include the display area DA and the peripheral area PA. The pixel circuit PC and light-emitting diodes LED electrically connected to the pixel circuit PC may be arranged in the display area DA, and repair circuits RPC may be arranged in the peripheral area PA. The peripheral area PA may be a non-display area in which the light-emitting diode LED is not arranged.

The pixel circuit PC may include a first thin-film transistor TFT1, and the repair circuit RPC may include a second thin-film transistor TFT2. According to an embodiment, each of the first thin-film transistor TFT1 and the second thin-film transistor TFT2 may correspond to the sixth transistor T6 described with reference to FIG. 4A.

A substrate 100 may include a glass material or polymer resin. According to an embodiment, the substrate 100 may have a multi-layer structure in which a base layer including polymer resin and a barrier layer including an inorganic insulating material may be alternately stacked each other. The base layer may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc. The barrier layer may include an inorganic insulating material, such as silicon oxide, silicon nitride, silicon oxynitride, etc.

A first insulating layer 101 may be disposed on the substrate 100. The first insulating layer 101 may include an inorganic insulating material, such as silicon oxide, silicon nitride, silicon oxynitride, etc., and may include a single-layer or multi-layer structure including the above-described inorganic insulating material.

The repair line RPL may be disposed on the first insulating layer 101. The repair line RPL may extend from the peripheral area PA to the display area DA. The repair line RPL may include a conductive material such as metal, for example, molybdenum (Mo), aluminum (Al), copper (Cu), titanium (Ti), etc., and may include a single-layer or multi-layer structure including the above-described material. According to an embodiment, the repair line RPL may be disposed between the substrate 100 and the first insulating layer 101.

A second insulating layer 102 may be disposed over the repair line RPL. The second insulating layer 102 may include an inorganic insulating material, such as silicon oxide, silicon nitride, silicon oxynitride, etc., and may include a single-layer or multi-layer structure including the above-described inorganic insulating material.

The first thin-film transistor TFT1 and the second thin-film transistor TFT2 may be disposed on the second insulating layer 102. The first thin-film transistor TFT1 and the second thin-film transistor TFT2 may have substantially the same or similar structures. The first thin-film transistor TFT1 is described below.

A semiconductor layer Act may be disposed on the second insulating layer 102. The semiconductor layer Act may include a channel region, and source and drain regions arranged on opposite sides of the channel region. The semiconductor layer Act may include at least one oxide selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the semiconductor layer Act may be an InSnZnO (ITZO) semiconductor layer, an InGaZnO (IGZO) semiconductor layer, or the like within the spirit and the scope of the disclosure.

A gate electrode GE may be disposed over the semiconductor layer Act with a third insulating layer 103 therebetween. A portion of the semiconductor layer Act that overlaps the gate electrode GE in a plan view may serve as the channel region. The gate electrode GE may include a conductive material including molybdenum (Mo), aluminum (Al), copper (Cu), titanium (Ti), etc., and may include a single-layer or multi-layer structure including the above-described material.

The third insulating layer 103, which is a gate insulating layer, may include an inorganic insulating material, such as silicon oxide, silicon nitride, silicon oxynitride, etc., and may include a single-layer or multi-layer structure including the above-described inorganic insulating material.

The voltage line VL may be disposed over the repair line RPL to overlap the repair line RPL in a plan view. The voltage line VL may be disposed in a layer in which the repair line RPL is not disposed, and may be arranged in any one of the conductive layers disposed between the substrate 100 and the light-emitting diode LED. The voltage line VL may be any one of the voltage lines configured to transfer a constant voltage to the pixel circuit PC and the repair circuit RPC. For example, as described with reference to FIGS. 4A, 5A, and 5B, the voltage line VL may be any one of the first voltage line VL1, the second voltage line VL2, and the third voltage line VL3. By way of example, the voltage line VL may be the common voltage line VSSL.

Because the voltage line VL and the repair line RPL overlap each other in a plan view, an area required for the arrangement of wires may be reduced, and thus, a high-resolution display panel 1 may be implemented. According to an embodiment, the voltage line VL may be disposed over the second insulating layer 102 with the third insulating layer 103 therebetween. The voltage line VL may include a conductive material including molybdenum (Mo), aluminum (Al), copper (Cu), titanium (Ti), etc., and may include a single-layer or multi-layer structure including the above-described material.

A fourth insulating layer 105 may be disposed over the voltage line VL and the gate electrode GE. The fourth insulating layer 105 may include an inorganic insulating material, such as silicon oxide, silicon nitride, silicon oxynitride, etc., and may include a single-layer or multi-layer structure including the above-described inorganic insulating material.

A source electrode SE, a drain electrode DE, the second connection line CNL2, and the third connection line CNL3 may be disposed on the fourth insulating layer 105. The source electrode SE may be connected to the source region of the semiconductor layer Act, and the drain electrode DE may be connected to the drain region of the semiconductor layer Act. According to an embodiment, the source electrode SE of the first thin-film transistor TFT1 may be integrally formed with the second connection line CNL2, and the source electrode SE of the second thin-film transistor TFT2 may be integrally formed with the third connection line CNL3.

The second connection line CNL2 may extend from the source electrode SE of the first thin-film transistor TFT1 to overlap the repair line RPL in a plan view. At least one insulating layer, for example, the fourth insulating layer 105, may be disposed between the second connection line CNL2 and the repair line RPL. According to an embodiment, the fourth insulating layer 105 may have a groove that is thinner than the surrounding area in an area where the second connection line CNL2 and the repair line RPL overlap each other.

The third connection line CNL3 may extend from the source electrode SE of the second thin-film transistor TFT2 to overlap the repair line RPL in a plan view. At least one insulating layer, for example, the fourth insulating layer 105, may be disposed between the third connection line CNL3 and the repair line RPL. According to an embodiment, the fourth insulating layer 105 may have a groove that is thinner than the surrounding area in an area where the third connection line CNL3 and the repair line RPL overlap each other.

The source electrode SE, the drain electrode DE, the second connection line CNL2, and the third connection line CNL3 may include molybdenum (Mo), aluminum (Al), copper (Cu), titanium (Ti), etc., and may include a single-layer or multi-layer structure including the above-described material.

A fifth insulating layer 107 may be disposed over the source electrode SE, the drain electrode DE, the second connection line CNL2, and the third connection line CNL3, and may include an organic insulating material such as acryl, benzocyclobutene (BCB), polyimide, or hexamethyldisiloxane (HMDSO).

The light-emitting diode LED may include a pixel electrode 210, an opposite electrode 230, and an intermediate layer 220 disposed between the pixel electrode 210 and the opposite electrode 230. The intermediate layer 220 may further include an emission layer 222 arranged in correspondence with the pixel electrode 210, and a first functional layer 221 and a second functional layer 223 disposed under or below and/or on the emission layer 222.

The pixel electrode 210 may be disposed on the fifth insulating layer 107. The pixel electrode 210 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to an embodiment, the pixel electrode 210 may further include a conductive oxide layer on and/or under or below the above-described reflection layer. The conductive oxide layer may include indium tin oxide (ITO), indium zinc oxide (IZO), zinc oxide (ZnO), indium oxide (In₂O₃), indium gallium oxide (IGO) and/or aluminum zinc oxide (AZO). According to an embodiment, the pixel electrode 210 may have a three-layer structure of ITO layer/Ag layer/ITO layer.

A bank layer 109 may be disposed on the pixel electrode 210. The bank layer 109 may include an opening overlapping the pixel electrode 210 and may cover edges of the pixel electrode 210. An emission area of the light-emitting diode LED may be defined by the opening of the bank layer 109.

The intermediate layer 220 may be disposed on the bank layer 109 and the pixel electrode 210. The intermediate layer 220 may include the emission layer 222 arranged in the opening of the bank layer 109 to correspond to the pixel electrode 210. The emission layer 222 may include a polymer organic material or low-molecular weight organic material emitting light of a given color.

A functional layer may be further under or below and/or on the emission layer 222. For example, the first functional layer 221 may be further between the pixel electrode 210 and the emission layer 222, and the second functional layer 223 may be further between the emission layer 222 and the opposite electrode 230 described below. The first functional layer 221 may include a hole transport layer and/or a hole injection layer. The second functional layer 223 may include an electron transport layer and/or an electron injection layer.

The opposite electrode 230 may include a conductive material having a low work function. For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. By way of example, the opposite electrode 230 may further include a layer, such as ITO, IZO, ZnO, or In₂O₃, on a (semi)transparent layer including the above-described material. The opposite electrode 230 may be formed in common to correspond to pixel electrodes 210.

In case that the pixel circuit PC is a normal circuit, the light-emitting diode LED may be electrically connected to the source electrode SE of the first thin-film transistor TFT1 through the second connection line CNL2. For example, the pixel electrode 210 of the light-emitting diode LED may be electrically connected to the second connection line CNL2 through a contact hole penetrating the fifth insulating layer 107. The second connection line CNL2 may be integrally formed with the source electrode SE of the first thin-film transistor TFT1. The voltage line VL may be electrically connected to the repair line RPL to transfer a constant voltage to the driving voltage line PL.

An encapsulation layer 300 may be disposed over the light-emitting diode LED and may include at least one inorganic encapsulation layer and at least one organic encapsulation layer. As an embodiment, FIG. 6A shows the encapsulation layer 300 including a first inorganic encapsulation layer 310, an organic encapsulation layer 320, and a second inorganic encapsulation layer 330.

The first inorganic encapsulation layer 310 and the second inorganic encapsulation layer 330 may include an inorganic insulating material such as silicon oxide, silicon nitride, silicon oxynitride, etc. The first inorganic encapsulation layer 310 and the second inorganic encapsulation layer 330 may have a single-layer or multi-layer structure including the above-described material. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate.

FIG. 6B illustrates connection relationships between the repair line RPL, the second connection line CNL2, and the third connection line CNL3 based on the assumption that a defect has occurred in the pixel circuit PC. Referring to FIG. 6B, a portion of the second connection line CNL2 connected to the source electrode SE of the first thin-film transistor TFT1 may be removed. Accordingly, the second connection line CNL2 and the source electrode SE may be apart from each other, and the second connection line CNL2 and the pixel circuit PC may be electrically separated from each other. A portion of the second connection line CNL2 may be removed by using a laser. In this regard, a portion of the first connection line CNL1 electrically connecting the repair line RPL to the voltage line VL may be removed, and thus, the repair line RPL and the voltage line VL may be electrically separated from each other.

Each of the second connection line CNL2 and the third connection line CNL3 may be electrically connected to the repair line RPL. For example, a laser may be emitted from the bottom of the substrate 100 toward a lower surface of the second connection line CNL2 and a lower surface of the third connection line CNL3. The laser may form contact holes in the second insulating layer 102 and the fourth insulating layer 105 and may heat and melt the second connection line CNL2 and the third connection line CNL3. The second connection line CNL2 melted by the laser may be connected to the repair line RPL through a contact hole. In the same manner, the third connection line CNL3 melted by the laser may be connected to the repair line RPL through a contact hole. According to an embodiment, the fourth insulating layer 105 may have a groove overlapping an area irradiated with a laser. For example, each of an area where the second connection line CNL2 and the repair line RPL are connected to each other and an area where the third connection line CNL3 and the repair line RPL are connected to each other.

The light-emitting diode LED and the repair circuit RPC may be electrically connected to each other through the second connection line CNL2, the repair line RPL, and the third connection line CNL3. The light-emitting diode LED may emit light at a luminance corresponding to the magnitude of a current received from the repair circuit RPC.

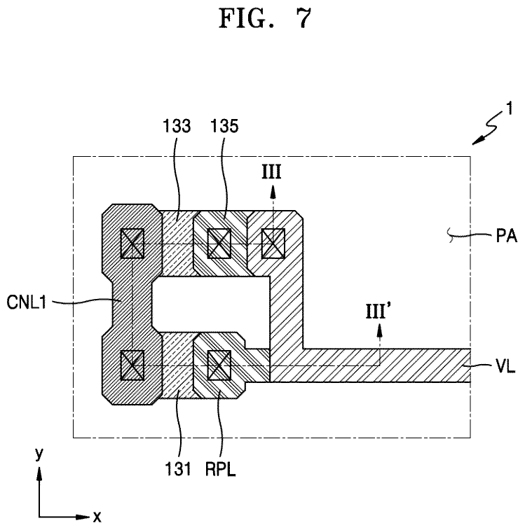

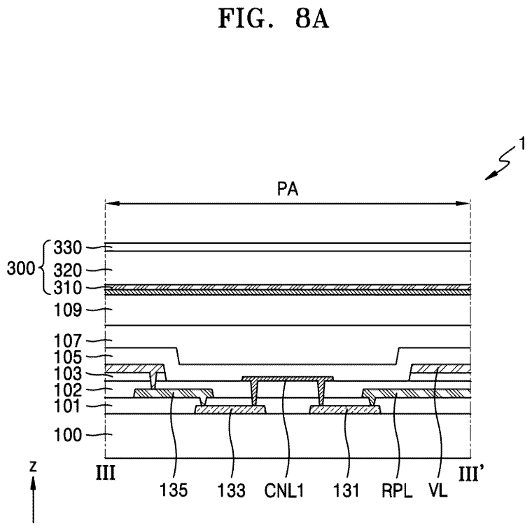

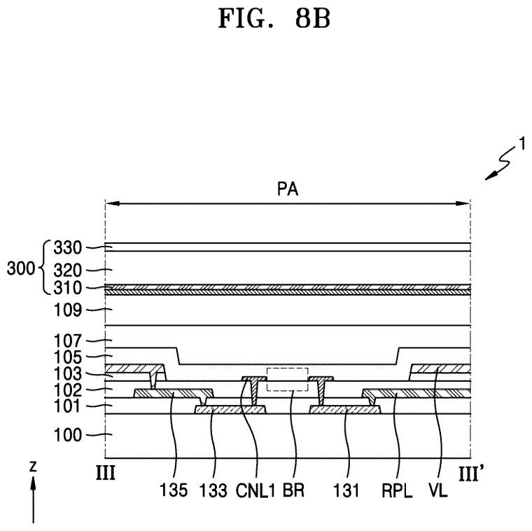

FIG. 7 is a schematic plan view of part of the display panel 1 according to an embodiment. FIG. 8A is a schematic cross-sectional view of the display panel 1 according to an embodiment. FIG. 8B is a schematic cross-sectional view describing a method of repairing a defective pixel in the display panel 1 shown in FIG. 8A. FIGS. 8A and 8B are schematic cross-sectional views of the display panel 1 shown in FIG. 7, taken along line III-III′.

Referring to FIGS. 7 and 8A, the display panel 1 may include the peripheral area PA, and the voltage line VL and the repair line RPL may be arranged in the peripheral area PA. The voltage line VL and the repair line RPL may extend from the peripheral area PA to the display area DA in a first direction (for example, an x-axis direction).

A first connection electrode 131 and a second connection electrode 133 may be disposed between the substrate 100 and the first insulating layer 101. The first connection electrode 131 and the second connection electrode 133 may include a conductive material such as metal, for example, molybdenum (Mo), aluminum (Al), copper (Cu), titanium (Ti), etc., and may include a single-layer or multi-layer structure including the above-described material.

The first insulating layer 101 may be disposed over the first connection electrode 131 and the second connection electrode 133, and a third connection electrode 135 and the repair line RPL may be disposed on the first insulating layer 101. The third connection electrode 135 may be disposed in a layer in which the repair line RPL is disposed, and the third connection electrode 135 may include a same material as that of the repair line RPL. The third connection electrode 135 may be connected to the second connection electrode 133 through a contact hole penetrating the first insulating layer 101, and the repair line RPL may be connected to the first connection electrode 131 through a contact hole penetrating the first insulating layer 101.

The second insulating layer 102 may be disposed over the third connection electrode 135 and the repair line RPL, and the first connection line CNL1 may be disposed on the second insulating layer 102. One end or an end of the first connection line CNL1 may be connected to the third connection electrode 135 through a contact hole penetrating the second insulating layer 102, and the other end of the first connection line CNL1 may be connected to the repair line RPL through a contact hole penetrating the second insulating layer 102. According to an embodiment, the first connection line CNL1 may be disposed in a layer in which the semiconductor layer Act described with reference to the figures is disposed, and may include a same material as that of the semiconductor layer Act. For example, the first connection line CNL1 may include at least one conductive oxide selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). A thickness of the first connection line CNL1 may be in a range of about 100 Å to about 200 Å. According to an embodiment, a thickness of the first connection line CNL1 may be about 150 Å. The first connection line CNL1 may be made conductive by injecting impurities into oxide or performing plasma treatment.

The voltage line VL may be disposed in a layer in which the repair line RPL is not disposed, and may be arranged in any one of the conductive layers disposed between the substrate 100 and the light-emitting diode LED. For example, as shown in FIGS. 8A and 8B, the voltage line VL may be disposed over the second insulating layer 102 with the third insulating layer 103 therebetween. The voltage line VL may include a conductive material including molybdenum (Mo), aluminum (Al), copper (Cu), titanium (Ti), etc., and may include a single-layer or multi-layer structure including the above-described material.

The voltage line VL may overlap the repair line RPL in a plan view. The voltage line VL and the repair line RPL may extend in the first direction (for example, the x-axis direction), and the repair line RPL may have a shape corresponding to that of the voltage line VL and may be disposed below the voltage line VL. The voltage line VL may be electrically connected to the repair line RPL through the first to third connection electrodes 131, 133, and 135 and the first connection line CNL1 in the peripheral area PA. Because the voltage line VL and the repair line RPL overlap each other in a plan view, an area required for the arrangement of wires may be reduced, and thus, a high-resolution display panel 1 may be implemented. Depending on a layer arrangement of the voltage line VL and repair line RPL, connection electrodes may be added or partially omitted.

Referring to FIG. 8B, as described with reference to FIG. 6B, the repair circuit RPC and the light-emitting diode LED of a defective pixel may be connected to the repair line RPL through a repair process. The second connection line CNL2 may be electrically separated from the pixel circuit PC and connected to the repair line RPL, and the third connection line CNL3 may be connected to the repair line RPL. In this regard, a portion of the first connection line CNL1 may be removed, and thus, the voltage line VL and the repair line RPL may be electrically separated from each other. For example, a cutting area BR between the first connection electrode 131 and the second connection electrode 133 may be irradiated with a laser, and thus, a portion of the first connection line CNL1 may be removed.

Because the first connection line CNL1 is positioned in the peripheral area PA, damage to the surrounding pixel may be reduced during cutting. Because the first connection line CNL1 may include a conductive oxide, the first connection line CNL1 may be relatively thin. Accordingly, the voltage line VL and the repair line RPL may be electrically separated from each other by readily cutting the first connection line CNL1 with a laser.

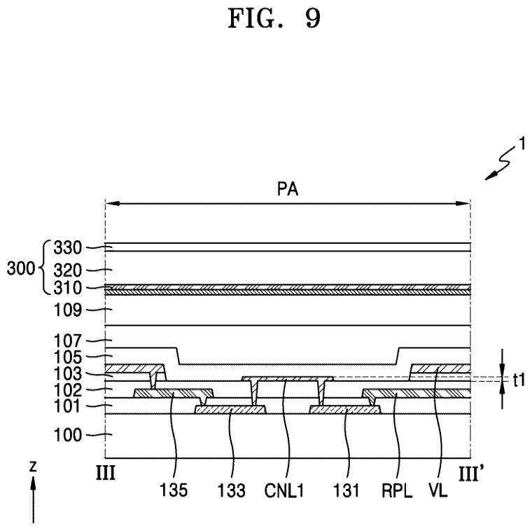

FIG. 9 is a schematic cross-sectional view of the display panel 1 according to an embodiment. FIG. 9 is similar to FIG. 8A, but there is a difference in that the first connection line CNL1 may include a metal.

Referring to FIG. 9, the first connection line CNL1 may include molybdenum (Mo), aluminum (Al), copper (Cu), titanium (Ti), etc., and may include a single-layer or multi-layer structure including the above-described material. According to an embodiment, the first connection line CNL1 may be a single aluminum layer. The first connection line CNL1 may have a first thickness t1. The first thickness t1 may be about 1,000 Å or less. As a comparative example, in case that a first thickness of a first connection line is greater than about 1,000 Å, it may be difficult to cut the first connection line by performing laser irradiation.

In the embodiment, the first thickness t1 of the first connection line CNL1 may be about 1,000 Å or less, and thus, during a repair process, the voltage line VL and the repair line RPL may be electrically separated from each other by readily cutting the first connection line CNL1 with a laser.

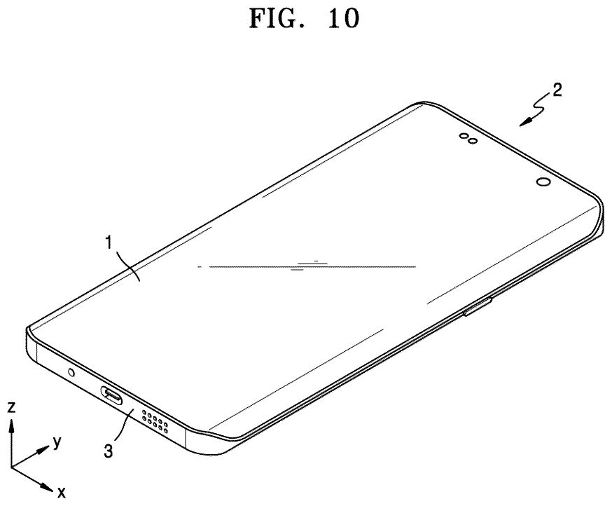

FIG. 10 is a schematic perspective view of an electronic device 2 according to an embodiment.

Referring to FIG. 10, the display panel 1 may be provided in the electronic device 2 to display a moving image or still image or perform data input and output. For example, the display panel 1 may be accommodated in a housing 3 of the electronic device 2. The housing 3 may be an element for protecting elements of the electronic device 2 and fixing the display panel 1.

Although FIG. 10 shows that the electronic device 2 is a mobile phone, one or more embodiments are not limited thereto. The electronic device 2 may be used as portable electronic devices such as a laptop, a tablet personal computer (PC), a mobile phone, a smartphone, a mobile communication terminal, an electronic notebook, an e-book, a portable multimedia player (PMP), a navigation system, and an ultra-mobile PC (UMPC).

By way of example, the electronic device 2 may be used as electronic devices for a television, a monitor, a billboard, and an Internet of things (IoT) device, or wearable electronic devices such as a smartwatch, a watch phone, a glasses-type display, and a head-mounted display (HMD). The electronic device 2 according to an embodiment may be an electronic device for use in a car's instrument panel, a center information display (CID) placed on a car's center fascia or dashboard, a room mirror display replacing a car's side mirror, or a display placed on the back of a front seat as entertainment for a car's rear seat.

While a display panel and an electronic device including the same have been described thus far, one or more embodiments are not limited thereto. For example, it will be understood that a method of repairing a defective pixel by using such a display panel and a method of manufacturing the display panel also fall within the scope of the disclosure.

According to one or more of the above embodiments, a display apparatus including a repair pixel circuit and an electronic device may be implemented. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A display panel comprising:
a pixel circuit disposed in a display area;
a light-emitting diode disposed in the display area;
a repair circuit disposed in a peripheral area outside of the display area;
a repair line extending from the peripheral area to the display area in a first direction;
a voltage line extending in the first direction; and
a first connection line electrically connecting the repair line to the voltage line.

2. The display panel of claim 1, wherein the pixel circuit comprises:
a first transistor comprising a semiconductor layer and a first gate electrode and electrically connected between a driving voltage line and a second node, wherein
the first gate electrode is disposed over the semiconductor layer and electrically connected to a first node;
a second transistor electrically connected between the first node and a data line;
a capacitor comprising a second electrode electrically connected between the first node and the second node;
a third transistor electrically connected between the first node and a first voltage line;
a fourth transistor electrically connected between the second node and a third node to which a pixel electrode of the light-emitting diode is electrically connected; and
a fifth transistor electrically connected between the third node and a second voltage line.

3. The display panel of claim 2, wherein the voltage line comprises one of the first voltage line and the second voltage line.

4. The display panel of claim 2, wherein
the pixel circuit further comprises a sixth transistor electrically connected between the second node and a third voltage line, and
the voltage line comprises one of the first voltage line, the second voltage line, and the third voltage line.

5. The display panel of claim 2, wherein
the light-emitting diode comprises a pixel electrode, a common electrode disposed over the pixel electrode, and an intermediate layer disposed between the pixel electrode and the common electrode, and
the voltage line comprises a common voltage line that transfers a common voltage to the common electrode.

6. The display panel of claim 2, wherein
the semiconductor layer comprises an oxide semiconductor material, and
the first connection line and the semiconductor layer are disposed in a same layer.

7. The display panel of claim 2, further comprising:
a first insulating layer disposed below the semiconductor layer,
wherein the repair line is disposed below the first insulating layer.

8. The display panel of claim 1, wherein the first connection line comprises a conductive oxide material.

9. The display panel of claim 1, wherein
the first connection line comprises a metal, and
a thickness of the first connection line is about 1,000 Å or less.

10. The display panel of claim 1, further comprising:
a second connection line electrically connecting the pixel circuit or the repair line to the light-emitting diode.

11. The display panel of claim 10, further comprising:
a third connection line electrically connected to the repair circuit and overlapping the repair line,
wherein, in case that the second connection line is electrically connected to the repair line, the third connection line is electrically connected to the repair line.

12. The display panel of claim 10, wherein, in case that the second connection line is electrically connected to the repair line, the first connection line is cut, and the repair line and the voltage line are electrically separated from each other.

13. The display panel of claim 1, wherein the repair line overlaps the voltage line in a plan view.

14. An electronic device comprising:
a display panel comprising a display area in which a plurality of pixels are disposed and a peripheral area outside of the display area,
wherein the display panel comprises:
a pixel circuit disposed in the display area;
a light-emitting diode disposed in the display area;
a repair circuit disposed in the peripheral area outside of the display area;
a repair line extending from the peripheral area to the display area in a first direction;
a voltage line extending in the first direction; and
a first connection line electrically connecting the repair line to the voltage line.

15. The electronic device of claim 14, wherein the pixel circuit comprises:
a first transistor comprising a semiconductor layer and a first gate electrode and electrically connected between a driving voltage line and a second node, the first gate electrode being disposed over the semiconductor layer and electrically connected to a first node;
a second transistor electrically connected between the first node and a data line;
a capacitor comprising a second electrode electrically connected between the first node and the second node;
a third transistor electrically connected between the first node and a first voltage line;
a fourth transistor electrically connected between the second node and a third node to which a pixel electrode of the light-emitting diode is electrically connected; and
a fifth transistor electrically connected between the third node and a second voltage line.

16. The electronic device of claim 15, wherein the voltage line comprises one of the first voltage line and the second voltage line.

17. The electronic device of claim 15, wherein
the pixel circuit further comprises a sixth transistor electrically connected between the second node and a third voltage line, and
the voltage line comprises one of the first voltage line, the second voltage line, and the third voltage line.

18. The electronic device of claim 15, wherein the semiconductor layer comprises an oxide semiconductor material.

19. The electronic device of claim 14, wherein
the display panel further comprises a second connection line electrically connecting the light-emitting diode to the pixel circuit or the repair line,
in case that the second connection line is electrically connected to the repair line, the first connection line is cut, and the repair line and the voltage line are electrically separated from each other.

20. The electronic device of claim 14, wherein the first connection line comprises a conductive oxide material.

21. The electronic device of claim 14, wherein
the first connection line comprises a metal,
wherein a thickness of the first connection line is about 1,000 Å or less.
